(19) United States
(12) Patent Application Publication
(10) Pub. No.: US 2024/0192111 A1
(43) Pub. Date: Jun. 13, 2024

(54) SUBSTRATE LIQUID-TREATMENT DEVICE

(71) Applicant: Tokyo Electron Limited, Minato-ku, Tokyo (JP)

(72) Inventors: Hiroshi MARUMOTO, Koshi-shi, Kumamoto (JP); Suguen LEE, Koshi-shi, Kumamoto (JP); Masashi ENOMOTO, Koshi-shi, Kumamoto (JP)

(21) Appl. No.: 18/552,108

(22) PCT Filed: Mar. 22, 2022
(86) PCT No.: PCT/JP2022/013307

§ 371 Date: Sep. 22, 2023

(30) Foreign Application Priority Data
Apr. 1, 2021 (JP) 2021-063140

(51) Int. Cl. G01N 15/075; G01N 15/00; H01L 21/67

(52) U.S. Cl. CPC G01N 15/075; G01N 2015/0011; H01L 21/67075

(57) ABSTRACT

A substrate liquid-processing apparatus includes: a processing tank storing a processing liquid for liquid-processing of a substrate within an inside; an imager configured to acquire an image of the processing liquid of the inside of the processing tank; and an image processor comprising a bubble data acquisitor configured to perform image processing on the image and to acquire bubble data representing the state of bubbles in the processing liquid.

### TECHNICAL FIELD

The present disclosure relates to a liquid-processing apparatus.

### BACKGROUND

Liquid-processing of substrates can be facilitated by controlling bubbles (an inert gas or the like) that are generated as the processing liquid boils and bubbles that are jetted into the processing liquid.

For example, in the substrate liquid-processing apparatus disclosed in Patent Document 1, a boiling state of a processing liquid may be detected, the pressure of the processing liquid may be adjusted depending on the boiling state, and the boiling state of the processing liquid may be adjusted. Consequently, the uniformity of substrate etching is improved.

### PRIOR ART DOCUMENTS

### Patent Documents

Patent Document 1: Japanese Patent Laid-Open Publication No. 2017-220618

Even for an engineer, it is not easy to visually determine the state of bubbles in a processing liquid. In particular, since there are individual differences in the sensing by engineers, it is difficult to accurately and stably determine the state of bubbles in a processing liquid by visual inspection.

### SUMMARY

The present disclosure provides a technique advantageous for accurately determining the state of bubbles in a processing liquid and stably liquid-processing a substrate.

An aspect of the present disclosure relates to a substrate liquid-processing apparatus including a processing tank storing a processing liquid for liquid-processing of a substrate within an inside: an imager configured to acquire an image of the processing liquid of the inside of the processing tank: and an image processor comprising a bubble data acquisitor configured to perform image processing on the image and to acquire bubble data representing the state of bubbles in the processing liquid.

The present disclosure is advantageous in accurately determining the state of bubbles in a processing liquid and stably liquid-processing a substrate.

### BRIEF DESCRIPTION OF DRAWINGS

FIG. 1 is a schematic plan view illustrating an overall configuration of an example of a substrate liquid-processing system.

FIG. 2 is a system diagram illustrating a configuration of an example of an etching apparatus incorporated in a substrate liquid-processing system.

FIG. 3 is a schematic vertical cross-sectional view of an example of a processing tank of an etching apparatus in a transverse direction.

FIG. 4 is a schematic vertical cross-sectional view of an example of a processing tank in a longitudinal direction.

FIG. 5 is a schematic plan view of an example of a processing tank.

FIG. 6 is a vertical cross-sectional view of an example of the processing tank in a transversal direction, in which only a lid and its peripheral members at a closed position are illustrated in detail.

FIG. 7 is a view illustrating an example of a captured image acquired by an imager.

FIG. 8 is a view illustrating an example of a processed image obtained by image-processing the captured image illustrated in FIG. 7.

FIG. 9 is a view illustrating another example of a processed image obtained by image-processing the captured image illustrated in FIG. 7.

FIG. 10 illustrates an example of image data (i.e., bubble data) created from representative values (especially, average values) of respective pixel values (especially, luminance values of respective pixels) of a plurality of images.

FIG. 11 is a functional block diagram illustrating an example of an image processor according to a first embodiment.

FIG. 12 is a flowchart illustrating an example of a substrate liquid-processing method (especially, a processing liquid adjustment method) according to the first embodiment.

FIG. 13 is a functional block diagram illustrating an example of an image processor according to a second embodiment.

FIG. 14 is a flowchart illustrating an example of a substrate liquid-processing method (especially, a bubbling state determination method) according to the second embodiment.

FIG. 15 is a functional block diagram illustrating an example of an image processor according to a third embodiment.

FIG. 16 is a flowchart illustrating an example of a substrate liquid-processing method (especially, a bubbling state adjustment method) according to the third embodiment.

FIG. 17 is a flowchart illustrating an example of the flow of liquid processing of a substrate.

FIG. 18 is a view illustrating an example of a bubbler according to a fourth embodiment.

FIG. 19 is a functional block diagram illustrating an example of an image processor according to the fourth embodiment.

### DETAILED DESCRIPTION

First, an entire substrate liquid-processing system 1A incorporating an etching apparatus (a substrate liquid-processing apparatus) 1 will be described.

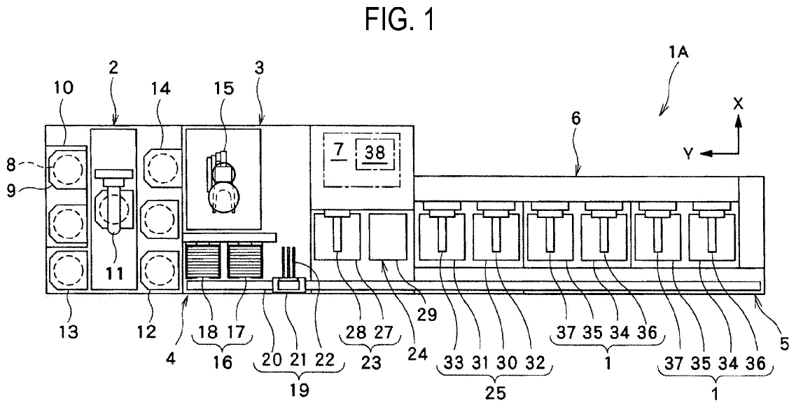

As illustrated in FIG. 1, a substrate liquid-processing system 1A includes a carrier carry-in and carry-out section 2, a lot forming section 3, a lot placement section 4, a lot transfer section 5, a lot processing section 6, and a controller 7.

Among these, the carrier carry-in and carry-out section 2 performs carry-in and carry-out of a carrier 9, which accommodates therein a plurality of (e.g., 25) substrates (silicon wafers) 8 aligned vertically in a horizontal orientation.

The carrier carry-in and carry-out section 2 is provided with: a carrier stage 10 on which a plurality of carriers 9 are placed; a carrier transfer mechanism 11, which transfers the carriers 9; carrier stocks 12 and 13, which temporarily store the carriers 9 therein; and a carrier pedestal 14 on which the carriers 9 are placed. Here, the carrier stock 12 temporarily stores the substrates 8 to be made into products before processing the substrates 8 in the lot processing section 6. In addition, the carrier stock 13 temporarily stores the substrates 8 to be made into products after processing the substrates 8 in the lot processing section 6.

The carrier carry-in and carry-out section 2 transfers the carriers 9 carried from the exterior into the carrier stage 10 to the carrier stock 12 or the carrier pedestal 14 by using the carrier transfer mechanism 11. In addition, the carrier carry-in and carry-out section 2 transfers the carrier 9 placed on the carrier pedestal 14 to the carrier stock 13 or the carrier stage 10 by using the carrier transfer mechanism 11. The carrier 9 transferred to the carrier stage 10 is carried out to the exterior.

The lot forming section 3 forms a lot including a plurality of (e.g., 50) substrates 8 to be processed simultaneously by combining the substrates 8 accommodated in one or more carriers 9. When forming a lot, the lot may be formed such that the patterned surfaces of two adjacent substrates 8 face each other, or a lot may be formed such that the patterned surfaces of substrates 8 all face the same direction.

The lot forming section 3 is provided with a substrate transfer mechanism 15 configured to transfer a plurality of substrates 8. In addition, the substrate transfer mechanism 15 may change the orientation of the substrates 8 from the horizontal orientation to the vertical orientation and from the vertical orientation to the horizontal orientation in the course of transferring the substrates 8.

The lot forming section 3 transfers the substrates 8 from the carrier 9 placed on the carrier pedestal 14 to the lot placement section 4 by using the substrate transfer mechanism 15, and places the substrates 8 forming a lot on the lot placement section 4. In addition, the lot forming section 3 transfers the lot placed on the lot placement section 4 to the carrier 9 placed on the carrier pedestal 14 by using the substrate transfer mechanism 15. The substrate transfer mechanism 15, as substrate supports that support a plurality of substrates 8, includes two types of supports, i.e., an unprocessed substrate support configured to support substrates 8 to be processed (before being transferred to the lot transfer section 5), and a processed substrate support configured to support processed substrates 8 (after being transferred to the lot transfer section 5). This makes it possible to prevent, for example, particles attached to, for example, the substrates 8 to be processed from being transferred and attached to the processed substrates 8 and the like.

In the lot placement section 4, a lot to be transferred between the lot forming section 3 and the lot processing section 6 by the lot transfer section 5 is temporarily placed (stands by) on a lot pedestal 16.

The lot placement section 4 is provided with a carry-in side lot pedestal 17 on which an unprocessed lot (before being transferred by the lot transfer section 5) is placed and a carry-out side lot pedestal 18 on which a lot to be processed (after being transferred by the lot transfer section 5) is placed. On the carry-in side lot pedestal 17 and the carry-out side lot pedestal 18, a plurality of substrates 8 for one lot are placed to be aligned in the front and the rear in the vertical orientation.

Then, in the lot placement section 4, a lot formed by the lot forming section 3 is placed on the carry-in side lot pedestal 17, and the lot is carried into the lot processing section 6 via the lot transfer section 5. In addition, in the lot placement section 4, the lot carried out from the lot processing section 6 via the lot transfer section 5 is placed on the carry-out side lot pedestal 18, and the lot is transferred to the lot forming section 3.

The lot transfer section 5 transfers lots between the lot placement section 4 and the lot processing section 6 or between the internal portions of the lot processing section 6.

The lot transfer section 5 is provided with a lot transfer mechanism 19 configured to perform lot transfer. The lot transfer mechanism 19 includes a rail 20 disposed along the lot placement section 4 and the lot processing section 6 and a mobile object 21 configured to move along the rail 20 in the state of holding a plurality of substrates 8. In the mobile object 21, a substrate holder 22 configured to hold a plurality of substrates 8 arranged in the front and the rear in the vertical orientation is provided to be movable back and forth.

The lot transfer section 5 receives the lot placed on the carry-in side lot pedestal 17 from the substrate holder 22 of the lot transfer mechanism 19 and delivers the lot to the lot processing section 6. In addition, the lot transfer section 5 receives the lot processed in the lot processing section 6 from the substrate holder 22 of the lot transfer mechanism 19 and delivers the lot to the carry-out side lot pedestal 18. Furthermore, the lot transfer section 5 performs lot transfer within the lot processing section 6 by using the lot transfer mechanism 19.

The lot processing section 6 performs processing such as etching, cleaning, or drying on a plurality of substrates 8, which are aligned in the front and the rear in the vertical orientation, as one lot.

The lot processing section 6 includes: a drying apparatus 23 configured to dry the substrates 8; a substrate holder cleaning apparatus 24 configured to clean the substrate holder 22: a cleaning apparatus 25 configured to clean the substrates 8: and two etching apparatuses 1 configured to etch the substrates 8, which are provided side by side.

The drying apparatus 23 includes a processing tank 27 and a substrate lifting mechanism 28 provided in the processing tank 27 to be movable upward and downward. A processing gas for drying (e.g., isopropyl alcohol (IPA)) is supplied to the processing tank 27. In the substrate lifting mechanism 28, a plurality of substrates 8 for one lot are held side by side in the front and the rear in the vertical orientation. The drying apparatus 23 receives the lot from the substrate holder 22 of the lot transfer mechanism 19 by using the substrate lifting mechanism 28 and raises and lowers the lot by using the substrate lifting mechanism 28, whereby the substrates 8 are dried by using the processing gas for drying supplied to the processing tank 27. In addition, the drying apparatus 23 delivers the lot from the substrate lifting mechanism 28 to the substrate holder 22 of the lot transfer mechanism 19.

The substrate holder cleaning apparatus 24 includes a processing tank 29 and is configured to be capable of supplying a processing liquid for cleaning and a drying gas to the processing tank 29. Thus, the substrate holder cleaning apparatus 24 cleans the substrate holder 22 by supplying the processing liquid for cleaning and then the drying gas to the substrate holder 22 of the lot transfer mechanism 19.

The cleaning apparatus 25 includes a processing tank 30 for cleaning and a processing tank 31 for rinsing, and substrate lifting mechanisms 32 and 33 are respectively provided in the processing tanks 30 and 31 to be movable upward and downward. In the processing tank 30 for cleaning, a processing liquid for cleaning (SC-1 or the like) is stored. The processing tank 31 for rinsing stores a processing liquid for rinsing (pure water or the like).

The etching apparatus 1 includes a processing tank 34 for etching and a processing tank 35 for rinsing, and substrate lifting mechanisms 36 and 37 are respectively provided in the processing tanks 34 and 35 to be movable upward and downward. In the processing tank 34 for etching, a processing liquid for rinsing (a phosphoric acid aqueous solution) is stored. The processing tank 35 for rinsing stores a processing liquid for rinsing (pure water or the like).

The cleaning apparatus 25 and the etching apparatus 1 have the same configuration. The etching apparatus 1 will be described. A plurality of substrates 8 for one lot are aligned and held in the front and the rear in the vertical orientation by the substrate lifting mechanism 36. In the etching apparatus 1, the lot is received by the substrate lifting mechanism 36 from the substrate holder 22 of the lot transfer mechanism 19 and is raised and lowered by the substrate lifting mechanism 36, thereby immersing the lot in the processing liquid for etching in the processing tank 34 and etching the substrates 8. Thereafter, the etching apparatus 1 delivers the lot from the substrate lifting mechanism 36 to the substrate holder 22 of the lot transfer mechanism 19. In addition, the substrate lifting mechanism 37 receives the lot from the substrate holder 22 of the lot transfer mechanism 19, and raises and powers the lot by the substrate lifting mechanism 37, thereby immersing the lot in the processing liquid for rinsing in the processing tank 35 and rinsing the substrates 8. Thereafter, the lot is delivered from the substrate lifting mechanism 37 to the substrate holder 22 of the lot transfer mechanism 19.

The controller 7 controls the operations of respective sections (the carrier carry-in and carry-out section 2, the lot forming section 3, the lot placement section 4, the lot transfer section 5, the lot processing section 6, and the etching apparatus 1) of the substrate liquid-processing system 1A.

The controller 7 is configured with, for example, a computer, and includes a computer-readable storage medium 38. In the storage medium 38, a program for controlling various processes to be executed in the etching apparatus 1 is stored. The controller 7 controls the operation of the etching apparatus 1 by reading and executing the program stored in the storage medium 38. In addition, the program may have been stored in the computer-readable storage medium 38 and may have been installed in the storage medium 38 of the controller 7 from another storage medium. The computer-readable storage medium 38 includes, for example, a hard disk (HD), a flexible disk (FD), a compact disk (CD), a magneto-optical disk (MO), a memory card, and the like.

As described above, in the processing tank 34 of the etching apparatus 1, the substrates 8 are subjected to liquid-processing (etching) by using an aqueous solution (phosphoric acid aqueous solution) of a chemical (phosphoric acid) having a predetermined concentration as a processing liquid (etching liquid).

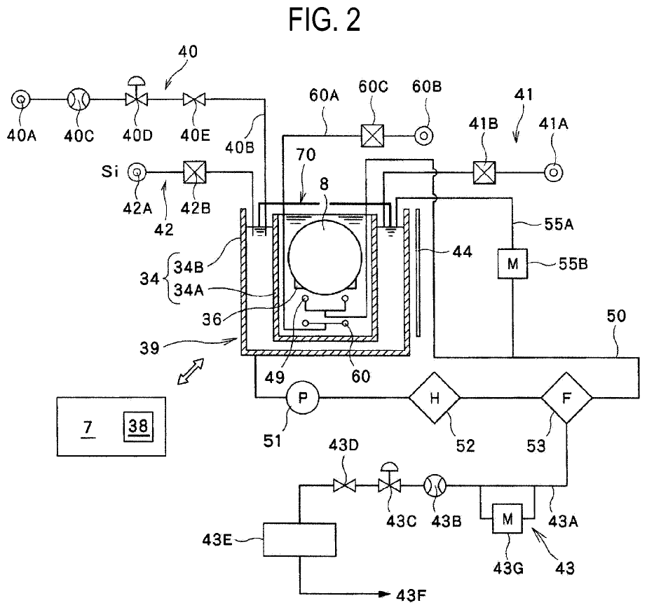

Next, the schematic configuration and piping system of the etching apparatus 1 will be described with reference to FIG. 2.

The etching apparatus 1 includes the above-described processing tank 34 that stores a phosphoric acid aqueous solution having a predetermined concentration as a processing liquid.

The processing tank 34 includes an inner tank 34A and an outer tank 34B. The phosphoric acid aqueous solution overflowing from the inner tank 34A flows into the outer tank 34B. The liquid level of the outer tank 34B is maintained lower than the liquid level of the inner tank 34A.

The upstream end of the circulation line 50 is connected to the bottom of the outer tank 34B. The downstream end of the circulation line 50 is connected to a processing liquid supply nozzle 49 installed in the inner tank 34A. A pump 51, a heater 52, and a filter 53 are disposed in the circulation line 50 in that order from the upstream side. By driving the pump 51, a circulating flow of the phosphoric acid aqueous solution is formed, which is sent from the outer tank 34B into the inner tank 34A through the circulation line 50 and the processing liquid supply nozzle 49, and then again flows out from the inner tank 34A to the outer tank 34B.

A liquid processor 39 is formed by the processing tank 34, the circulation line 50, and the devices (51, 52, 53, etc.) in the circulation line 50. A circulation system is configured by the processing tank 34 and the circulation line 50.

Below the processing liquid supply nozzle 49 in the inner tank 34A, a gas nozzle 60 configured to eject inert gas (e.g., nitrogen gas) bubbles (for bubbling) into the phosphoric acid aqueous solution in the inner tank 34A is provided. The gas nozzle 60 is supplied with an inert gas (e.g., nitrogen gas) from a gas source 60B through a flow regulator 60C including an opening and closing valve, a flow control valve, a flow meter, and the like.

The processing tank 34 is provided with the above-described substrate lifting mechanism 36. The substrate lifting mechanism 36 is capable of holding a plurality of substrates 8 in a state in which the substrates are horizontally spaced apart from each other in an upright orientation, and is capable of moving upward and downward in this state.

The etching apparatus 1 includes a phosphoric acid aqueous solution supplier 40 configured to supply a phosphoric acid aqueous solution to the liquid processor 39 and a pure water supplier 41 that supplies pure water to the liquid processor 39. The etching apparatus 1 also includes a silicon supplier 42 configured to supply a silicon solution to the liquid processor 39 and a phosphoric acid aqueous solution discharger 43 configured to discharge the phosphoric acid aqueous solution from the liquid processor 39.

The phosphoric acid aqueous solution supplier 40 supplies the phosphoric acid aqueous solution having a predetermined concentration to any area within the circulation system including the processing tank 34 and the circulation line 50, that is, within the liquid processor 39, preferably the outer tank 34B, as illustrated in the drawing. The phosphoric acid aqueous solution supplier 40 includes a phosphoric acid aqueous solution source 40A including a tank that stores the phosphoric acid aqueous solution, and a phosphoric acid aqueous solution supply line 40B that connects the phosphoric acid aqueous solution source 40A to the outer tank 34B. In addition, the phosphoric acid aqueous solution supplier 40 includes a flow meter 40C, a flow control valve 40D, and an opening and closing valve 40E which are disposed in the phosphoric acid aqueous solution supply line 40B in that order from the upstream side. The phosphoric acid aqueous solution supplier 40 is capable of supplying the phosphoric acid aqueous solution to the outer tank 34B at a controlled flow rate via the flow meter 40C and the flow control valve 40D.

The pure water supplier 41 supplies pure water to replenish the moisture evaporated by heating the phosphoric acid aqueous solution. This pure water supplier 41 includes a pure water source 41A configured to supply pure water at a predetermined temperature, and this pure water source 41A is connected to the outer tank 34B via a flow regulator 41B. The flow regulator 41B may include an opening and closing valve, a flow control valve, a flow meter, and the like.

The silicon supplier 42 includes a silicon source 42A, which is configured with a tank that stores a silicon-containing compound solution (e.g., a liquid in which colloidal silicon is dispersed), and a flow regulator 42B. The flow regulator 42B may include an opening and closing valve, a flow control valve, a flow meter, and the like.

The phosphoric acid aqueous solution discharger 43 is provided to discharge the phosphoric acid aqueous solution present in the circulation system including the liquid processor 39 and the circulation line 50, i.e., in the liquid processor 39. The phosphoric acid aqueous solution discharger 43 includes a discharge line 43A branched from the circulation line 50, and a flow meter 43B, a flow control valve 43C, an opening and closing valve 43D, and a cooling tank 43E which are sequentially provided in the discharge line 43A from the upstream side. The phosphoric acid aqueous solution discharger 43 may discharge the phosphoric acid aqueous solution at a controlled flow rate via the flow meter 43B and the flow control valve 43C.

The cooling tank 43E temporarily stores and cools the phosphoric acid aqueous solution flowing through the discharge line 43A. The phosphoric acid aqueous solution (see reference numeral 43F) flowing out from the cooling tank 43E may be discarded to a factory waste liquid system (not illustrated), or after removing the silicon contained in the phosphoric acid aqueous solution by a regenerator (not illustrated), the phosphoric acid aqueous solution may be sent to the phosphoric acid aqueous solution source 40A for reuse.

In the illustrated example, the discharge line 43A is connected to the circulation line 50 (the position of the filter drain in the drawing), but is not limited thereto, and may be connected to another portion within the circulation system (e.g., the inner tank 34A).

The discharge line 43A is provided with a silicon concentration meter 43G configured to measure the silicon concentration in the phosphoric acid aqueous solution. A phosphoric acid concentration meter 55B configured to measure the phosphoric acid concentration in the phosphoric acid aqueous solution is disposed in a branch line 55A branched from the circulation line 50 and connected to the outer tank 34B. The outer tank 34B is provided with a liquid level gauge 44 configured to detect the liquid level in the outer tank 34B.

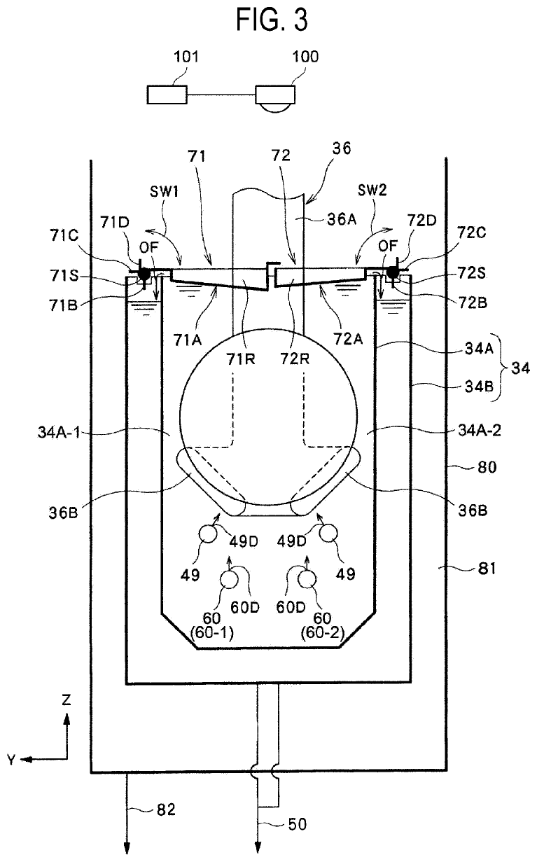

Next, the configuration of the processing tank 34 of the etching apparatus 1 will be described in detail with reference to FIGS. 3 to 6. For convenience of description, an XYZ orthogonal coordinate system is set and referred to as necessary. The negative X direction may be referred to as “front” or “forward”, the positive X direction may be referred to as “rear” or “rearward”, the negative Y direction may be referred to as “right” or “rightward”, and the positive Y direction may be referred to as “left” or “leftward”.

As described above, the processing tank 34 includes an inner tank 34A with an open top and an outer tank 34B with an open top. The inner tank 34A is housed inside the outer tank 34B. The phosphoric acid aqueous solution overflowing from the inner tank 34A flows into the outer tank 34B. While liquid-processing is being executed, most of the inner tank 34A including the bottom is immersed in the phosphoric acid aqueous solution in the outer tank 34B.

The outer tank 34B is housed inside a liquid receiving container (sink) 80, and a drain space 81 is formed between the outer tank 34B and the liquid receiving container 80. A drain line 82 is connected to the bottom of the drain space 81.

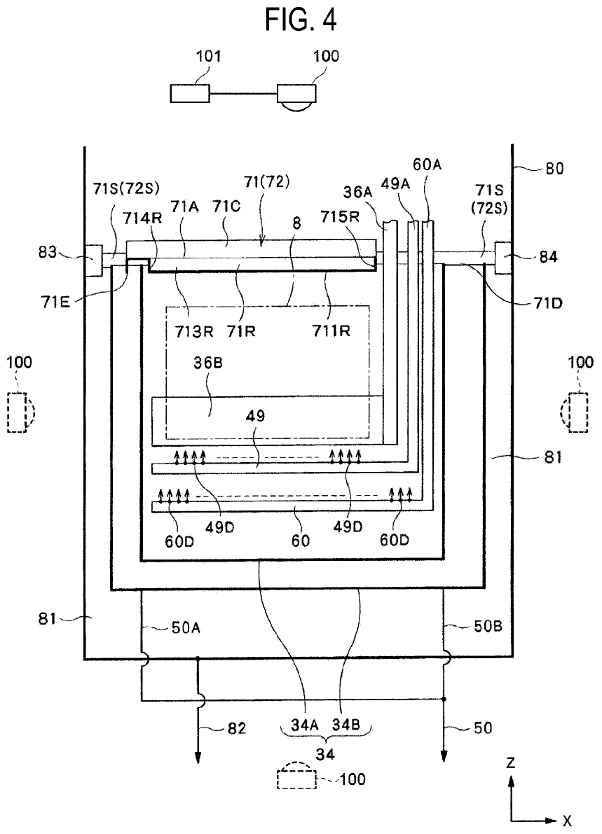

The processing liquid supply nozzle 49 is made of a cylindrical body extending in the X direction (horizontal direction) in the inner tank 34A. The processing liquid supply nozzle 49 discharges the processing liquid toward the substrates 8 held by the substrate lifting mechanism 36 from a plurality of ejection ports 49D (see FIGS. 3 and 4) bored in the peripheral surface of the processing liquid supply nozzle 49. Although two processing liquid supply nozzles 49 are provided in the drawing, three or more processing liquid supply nozzles 49 may be provided. A processing liquid (phosphoric acid aqueous liquid) is supplied to the processing liquid supply nozzle 49 from a pipe 49A extending in the vertical direction.

The gas nozzle 60 is a cylindrical body extending in the X direction (horizontal direction) at a height position lower than the processing liquid supply nozzle 49 in the inner tank 34A. The gas nozzle 60 ejects inert gas (e.g., nitrogen gas) bubbles from a plurality of ejection ports 60D (see FIGS. 3 and 4) bored in the peripheral surface thereof. The bubbling of the inert gas is capable of stabilizing the boiling state of the phosphoric acid aqueous solution in the inner tank 34A. An inert gas is supplied to the gas nozzle 60 from a pipe 60A extending in the vertical direction.

The substrate lifting mechanism 36 includes a support plate 36A extending in the vertical direction (the Z direction) and configured to be raised and lowered by a lifting mechanism (not illustrated), and a pair of substrate support members 36B extending in the horizontal direction (the X direction) with one end supported by the support plate 36A. Each substrate support member 36B includes a plurality of (e.g., 50 to 52) substrate support grooves (not illustrated) arranged at intervals in the horizontal direction (the X direction). The peripheral edge portions of substrates 8 are inserted into the substrate support grooves, respectively. The substrate lifting mechanism 36 is capable of holding the plurality of (e.g., 50 to 52) substrates 8 in a vertical operation in the state of being spaced apart from each other in the horizontal direction (the X direction). The substrate lifting mechanism 36 is well known in the art, and detailed illustration and description of the structure thereof are omitted.

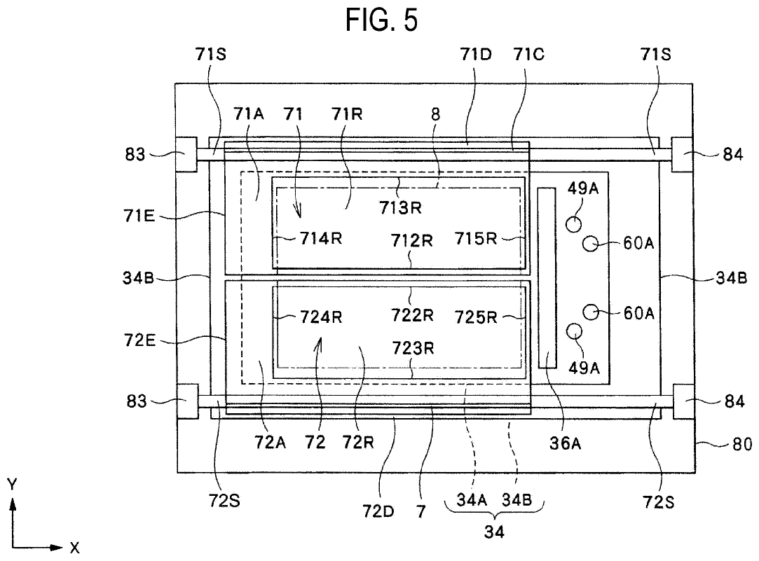

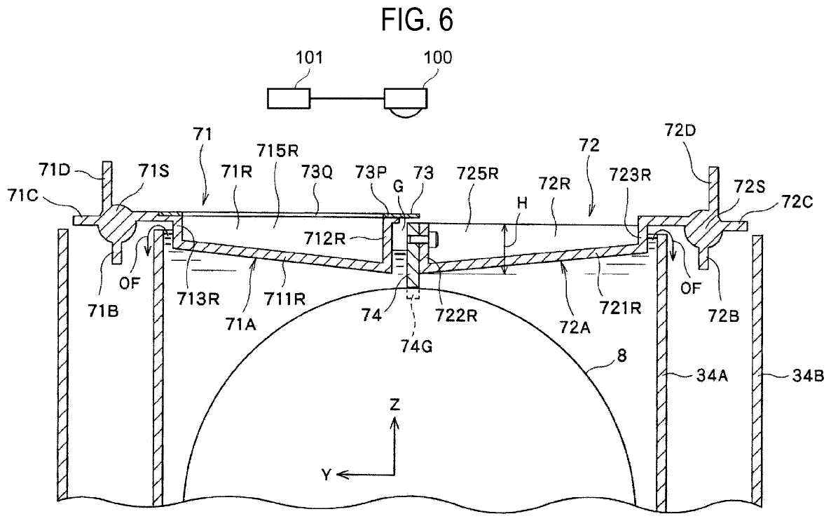

The processing tank 34 is provided with a first lid 71 and a second lid 72 configured to open and close the upper opening of the inner tank 34A. The first lid 71 and the second lid 72 are coupled to rotary shafts 71S and 72S, respectively, which extend in the horizontal direction (the X direction). The rotary shafts 71S and 72S are connected to a bearing 83 and a rotary actuator 84 fixed to the liquid receiving container 80 (see FIGS. 4 and 5). By operating the rotary actuator 84, the first lid 71 and the second lid 72 are rotatable (turnable) about the rotation axes thereof, respectively, which extend in the horizontal direction (the X direction) (see arrows SW1 and SW2 in FIG. 3). The first lid 71 and the second lid 72 are rotated between a closed position (the position illustrated in FIGS. 3 and 6) where the first and second lids cover a first region (left half) and a second region (right half) of the upper opening of the inner tank 34A) and an open position where the first and second lids open the first and second regions of the upper opening of the inner tank 34A in a substantially upright state.

The first lid 71 and the second lid 72 do not cover the regions of the upper opening of the inner tank 34A where the support plate 36A and the pipes 49A and 60A are provided.

During normal operation of the etching apparatus 1, the first lid 71 and the second lid 72 are in the closed position except when the substrates 8 held by the substrate lifting mechanism 36 are carried into and out of the inner tank 34A. This prevents the temperature of the phosphoric acid aqueous solution in the inner tank 34A from dropping, and also suppresses the water vapor generated from the boiling phosphoric acid aqueous solution from escaping to the exterior of the processing tank 34.

The first lid 71 includes: a main body 71A that is substantially rectangular when viewed from directly above: a first splash shielding portion 71B, a second splash shielding portion 71C, and a closing portion 71D that extend in the X direction; and a third splash shielding portion 71E that extends in the Y direction. Similarly, the second lid 72 includes: a main body 72A that is substantially rectangular: a first splash shielding portion 72B, a second splash shielding portion 72C, and a closing portion 72D that extend in the X direction; and a third splash shielding portion 72E that extends in the Y direction.

A large rectangular recess 71R is formed in the top surface of the main body 71A. The recess 71R is defined by a bottom wall 711R and four side walls 712R, 713R, 714R, and 715R. A large rectangular recess 72R is formed in the top surface of the main body 72A. The recess 72R is defined by a bottom wall 721R and four side walls 722R, 723R, 724R, and 725R.

In order not to prevent the phosphoric acid aqueous solution from overflowing from the inner tank 34A to the outer tank 34B (see the arrows OF in FIG. 6) when the first lid 71 is in the closed position, a gap is provided between the side walls of the inner tank 34A and the side walls 712R and 713R that face the same closely. Although not illustrated, a plurality of V-shaped cutouts are formed at intervals in the upper ends of four side walls of the inner tank 34A so that the overflow can occur smoothly.

The bottom wall 711R of the first lid 71 is inclined so as to become higher as it separates from the second lid 72 in the Y direction (as it approaches the side wall of the inner tank 34A in the Y direction). This inclination facilitates the above-mentioned overflow.

Since the phosphoric acid aqueous solution in the inner tank 34A is in a boiling state, droplets of the phosphoric acid aqueous solution also splash outward from the inner tank 34A together with the phosphoric acid aqueous solution overflowing from the inner tank 34A to the outer tank 34B. The splashing droplets collide with the first splash shielding portion 71B of the first lid 71 in the closed position and falls into the space between the side walls of the inner tank 34A and the side walls of the outer tank 34B. Thus, the splashing droplets do not scatter to the exterior of the outer tank 34B. Preferably, the lower end of the first splash shielding portion 71B of the first lid 71 in the closed position is at least lower than the upper end of the side wall of the inner tank 34A adjacent thereto.

When the first lid 71 is in the open position, the second splash shielding portion 71C performs the same function as the first splash shielding portion 71B when the first lid 71 is in the closed position. Preferably, the lower end of the first splash shielding portion 71B of the first lid 71 in the open position is at least lower than the upper end of the side wall of the inner tank 34A adjacent thereto.

When the first lid 71 is in the open position, the closing portion 71D covers the area from the rotary shaft 71S to the side walls of the outer tank 34B in the gap between the upper ends of the side walls of the inner tank 34A and the upper ends of the side walls of the outer tank 34B. The closing portion 71D guides the liquid adhering to the top surface of the main body 71A when the first lid 71 is in the closed position to a drain space 81 between the outer tank 34B and the liquid receiving container 80 when the first lid 71 is in the open position. As a result, for example, when a wet substrate passes above the processing tank 34, the liquid dropped from the substrate is guided to the drain space 81, thereby preventing the liquid from flowing into the outer tank 34B. The liquid that has entered the drain space 81 is discarded from the drain line 82.

The third splash shielding portion 71E is provided on the far side from the substrate lifting mechanism 36 to extend above the space between the side walls of the inner tank 34A and the side walls of the outer tank 34B. The third splash shielding portion 71E extends from the rotary shaft 71S in the Y direction along the end edge of the first lid 71 over the entire length of the end edge. The third splash shielding portion 71E performs the same function as the first splash shielding portion 71B when the first lid 71 is in the closed position. Preferably, the lower end of the third splash shielding portion 71E of the first lid 71 in the open position is at least lower than the upper end of the side wall of the inner tank 34A adjacent thereto.

It is not necessary to provide a splash shielding portion extending along the end edge of the first lid 71 extending in the Y direction on the side close to the substrate lifting mechanism 36. This is because the phosphoric acid solution, which scatters in the positive X direction, collides with the support plate 36A of the substrate lifting mechanism 36, the pipes 49A and 60A, and the like and hardly reaches the outer tank 34B.

The second lid 72 is provided substantially mirror-symmetrically with respect to the first lid 71, and the structures of the first lid 71 and the second lid 72 are substantially the same. Accordingly, the description of the configuration and action of the first lid 71 may be used for the description of the configuration and action of the second lid 72. The reference numerals of the corresponding members of the first lid 71 and the second lid 72 (members at symmetrical positions, members having the same function) have the same alphabet at the ends thereof and differ only in whether first two digits of the reference numerals are “71” or “72”.

As illustrated in FIG. 6, when the first lid 71 and the second lid 72 are in the closed position, the side wall 712R extending upward from the bottom wall 711R of the first lid 71 and the side wall 722R extending upward from the bottom wall 721R of the second lid 72 face each other, and a gap G having a height H is formed between the side walls. By providing the recesses 71R and 72R, it is possible to suppress an increase in the weight of the first lid 71 and the second lid 72 due to the provision of the gap having the height H.

A discussion is made on a case where the bottom surface of the main body 71A of the first lid 71 (the bottom surface of the bottom wall 711R) and the bottom surface of the main body 72A of the second lid 72 (the bottom surface of the bottom wall 721R), which are in the closed position as illustrated in FIG. 6, are in contact with the liquid surface of the processing liquid in the inner tank 34A. In this case, the boiling phosphoric acid aqueous solution may splash upward from the gap between the first lid 71 and the second lid and may scatter around. However, by providing the gap G with the height H as described above, it becomes difficult for the boiling processing liquid to splash from the gap G to the exterior. To achieve this effect, the height H may be, for example, about 5 cm or more.

When the processing liquid in the inner tank 34A is a phosphoric acid aqueous solution in a boiling state, at least the main bodies 71A and 72A of the first lid 71 and the second lid 72 are made of a material (e.g., quartz, etc.) that is impervious to the processing liquid. When the main bodies 71A and 72A are made of quartz, there is a risk that the quartz will collide with each other, causing cracking or chipping. In order to prevent this, it is desirable to provide a gap between the main bodies 71A and 72A such that the main bodies 71A and 72A are not brought into contact each other when the first lid 71 and the second lid 72 are in the closed position.

When the gap is provided between the main bodies 71A and 72A, the phosphoric acid aqueous solution in the processing tank 34, particularly in the inner tank 34A, may scatter outward through the gap. However, by providing the gap G with the height H as described above, it is possible to at least greatly suppress the scattering of the phosphoric acid aqueous solution from the gap G.

A discussion is made on a case where the bottom wall 711R (721R) is inclined as described above and the bottom wall 711R (721R) is brought into contact with the phosphoric acid aqueous solution in the inner tank 34A in order to facilitate overflow. When there is no side wall 712R (722R) extending upward from the bottom wall 711R (721R), the tip of the bottom wall 711R (721R) is submerged in the phosphoric acid aqueous solution. However, by providing the side wall 712R (722R) extending upward from the bottom wall 711R (721R) as described above, it is possible to make the height position of the liquid surface of the phosphoric acid aqueous solution lower than the upper end of the side wall 712R (722R).

As illustrated in FIG. 6, it is desirable to provide a cover 73, which extends up to or beyond the tip of the gap G and covers the gap G from above, to one of the main body 71A of the first lid 71 and the main body 72A of the second lid 72 (here, the main body 71A) and the other (here, the main body 72A). By providing the cover 73, it is possible to prevent the processing liquid from splashing upward through the gap G. Note that the cover 73 (and a plate-like body 73P) is not illustrated in FIGS. 3 to 5 in order to avoid complicating the drawings.

Since the gap G has the height H, the momentum of droplets of the processing liquid scattered from the liquid surface of the phosphoric acid aqueous solution in the inner tank 34A weakens until colliding with the cover 73. For this reason, the processing liquid that has collided with the cover 73 does not splash out sideways.

For example, as illustrated in FIG. 6, the cover 73 may be provided by mounting the plate-like body 73P having a substantially rectangular cut-out portion 73Q matching the outline of the recess 71R of the first lid 71 on the top surface of the main body 71A of the first lid 71. In this case, the cover 73 is configured by the end edge portion of the plate-like body 73P.

As illustrated in FIG. 6, a gap may be provided between the cover 73 and the second lid 72 when the first lid 71 and the second lid 72 are in the closed position. Alternatively, the cover 73 and the second lid 72 may be in contact with each other when the first lid 71 and the second lid 72 are in the closed position. In this case, the cover 73 serves as a seal that closes the upper end of the gap G.

It is preferable to form the cover 73 from resin materials that are unlikely to be damaged even if collides with quartz, are flexible enough not to damage quartz when the cover 73 is brought into contact with the second lid 72, and have relatively high corrosion resistance. Examples of such resin materials include fluorine-based resin materials such as PTFE and PFA.

The cover 73 may be formed integrally with the first lid 71. In addition, the cover 73 may not be provided. When the cover 73 is not provided, it is preferable to make the height H higher than that in the case where the cover 73 is provided.

In addition, a substrate retainer 74 is provided on one of the main body 71A of the first lid 71 and the main body 72A of the second lid 72 (here, the tip of the main body 72A of the second lid 72). In the bottom surface of the substrate retainer 74, along the arrangement direction (X direction) of substrates 8, a plurality of substrate holding grooves 74G are arranged at the same X-direction positions with the same pitch as the substrate holding grooves (not illustrated) in the substrate support members 36B. A peripheral edge portion of one substrate 8 is accommodated in each of the substrate holding grooves 74G.

In the illustrated embodiment, the substrate retainer 74 is configured with an elongated plate-like body formed separately from the second lid 72, and is fixed to the main body 72A of the second lid 72 by screw-fastening. Alternatively, the substrate retainer 74 may be configured integrally with the second lid 72. In either case, the substrate retainer 74 constitutes a part of the side wall 722R of the main body 72A of the second lid 72.

When the substrates 8 are being processed, the substrate retainer 74 provided on the second lid 72, which is in the closed position, engages with the substrates 8 supported by the substrate support members 36B to prevent or suppress the substrates 8 from displacing upward. Therefore, even if the processing liquid is ejected from the processing liquid supply nozzle 49 at a large flow rate, even if the boiling level of the processing liquid in the inner tank 34A becomes high, or even if bubbling of nitrogen gas is performed vigorously, the possibility of the substrates 8 being separated from the substrate support members 36B is eliminated.

Next, the operation of the etching apparatus 1 will be described. First, the phosphoric acid aqueous solution supplier 40 supplies a phosphoric acid aqueous solution to the outer tank 34B of the liquid processor 39. After a predetermined period of time has passed since the start of supply of the phosphoric acid aqueous solution, the pump 51 of the circulation line 50 is activated to form the circulation flow that circulates in the above-described circulation system.

In addition, the heater 52 of the circulation line 50 is activated to heat the phosphoric acid aqueous solution in the inner tank 34A such that the phosphoric acid aqueous solution reaches a predetermined temperature (e.g., 160 degrees C.). By the time the heater 52 starts heating at the latest, the first lid 71 and the second lid 72 are placed in the closed position. The phosphoric acid aqueous solution at 160 degrees C. is in a boiling state. When the phosphoric acid concentration meter 55B detects that the concentration of the phosphoric acid exceeds a predetermined control upper limit value due to evaporation of water due to the boiling, pure water is supplied from the pure water supplier 41.

Before putting one lot of substrates 8 into the phosphoric acid aqueous solution in the inner tank 34A, the concentration of silicon in the phosphoric acid aqueous solution present in the circulation system (including the inner tank 34A, the outer tank 34B, and the circulation line 50) is adjusted. This concentration of silicon affects the etching selectivity of a silicon nitride film to a silicon oxide film. The concentration of silicon may be adjusted by immersing dummy substrates in the phosphoric acid aqueous solution in the inner tank 34A, or by supplying a silicon-containing compound solution from the silicon supplier 42 to the outer tank 34B. In order to identify that the concentration of silicon in the aqueous phosphoric acid solution present in the circulation system is within a predetermined range, the aqueous phosphoric acid solution may be caused to flow to the discharge line 43A and the concentration of silicon may be measured by the silicon concentration meter 43G.

After the adjustment of the concentration of silicon concentration adjustment is completed, the first lid 71 and the second lid 72 are moved to the open position. Then, a plurality of (e.g., 50) substrates 8 forming one lot (also called a “processing lot” or “batch”) held by the substrate lifting mechanism 36 are immersed in the phosphoric acid aqueous solution in the inner tank 34A. Immediately thereafter, the first lid 71 and the second lid 72 are returned to the closed position. By immersing the substrates 8 in the phosphoric acid aqueous solution for a predetermined period of time, the substrates 8 are subjected to wet etching (liquid-processing).

By placing the first lid 71 and the second lid 72 at the closed position during the etching of the substrates 8, the temperature drop near the liquid surface of the phosphoric acid aqueous solution in the inner tank 34A is suppressed, which makes it possible to make the temperature distribution of the phosphoric acid aqueous solution in the inner tank 34A small. In addition, because the inner tank 34A is immersed in the phosphoric acid aqueous solution in the outer tank 34B, the temperature drop of the phosphoric acid aqueous solution in the inner tank 34A due to heat dissipation from the wall of the inner tank 34A is suppressed, which also makes it possible to make the temperature distribution of the phosphoric acid aqueous solution in the inner tank 34A small. Therefore, the in-plane uniformity and inter-plane uniformity of the etching amounts of the substrates 8 can be maintained high.

Since silicon is eluted from the substrates 8 during the processing of one lot of substrates 8, the concentration of silicon in the phosphoric acid aqueous solution present in the circulation system increases. In order to maintain or intentionally change the concentration of silicon in the phosphoric acid aqueous solution present in the circulation system during the processing of one lot of substrates, the phosphoric acid aqueous solution may be supplied by the phosphoric acid aqueous solution supplier 40 while the phosphoric acid aqueous solution is being discharged by the phosphoric acid aqueous solution discharger 43.

When the one lot of substrates 8 is processed as described above, the first lid 71 and the second lid 72 are moved to the open position, and the substrates 8 are carried out from the inner tank 34A.

Thereafter, the first lid 71 and the second lid 72 are moved to the closed position again, and after adjusting the temperature, the concentration of phosphoric acid, and the concentration of silicon of the phosphoric acid aqueous solution in the circulation system, substrates 8 of another lot are processed in the same manner as described above.

As illustrated in FIGS. 3, 4, and 6, the above-described etching apparatus 1 further includes an imager (a camera) 100 configured to acquire an image inside the inner tank (a processing tank) 34A, and an image processor 101 configured to perform image processing on the image acquired by the imager 100.

The imager 100 of the present example is fixedly supported by a support frame (not illustrated) above the inner tank 34A, in which the processing liquid for liquid-processing (especially, etching) of the substrates 8 is stored, and acquires an image of the interior of the inner tank 34A from above under the control of the controller 7.

The first lid 71 and the second lid 72 (especially, the main bodies 71A and 72A) of the present example are made of a transparent material such as quartz. The imager 100 receives imaging light transmitted through the first lid 71 and the second lid 72 and acquires an image of the processing liquid inside the inner tank 34A.

The image acquired by the imager 100 may be a moving image or a still image.

The installation position and imaging direction of the imager 100 are not limited, and a plurality of imagers 100 with different imaging directions may be provided. As illustrated in FIG. 4, an image of the interior of the inner tank 34A may be acquired from the side or the bottom by an imager 100 installed to the side (e.g., in the X direction) or the bottom of the inner tank 34A. When the imager 100 is installed on the side or below the inner tank 34A, the members interposed between the imager 100 and the interior of the inner tank 34A (i.e., the inner tank 34A, the outer tank 34B, and the container 80) are made of a transparent material through which photographing light can pass.

The image processor 101 may be configured with the controller 7, or may be provided separately from the controller 7. When the image processor 101 is provided separately from the controller 7, the image processor 101 may perform various processes under the control of the controller 7.

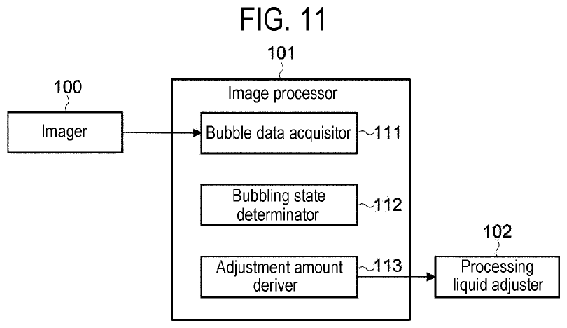

The image processor 101 has a bubble data acquisitor (see FIG. 11, etc., which will be described later). The bubble data acquisitor performs image processing on the captured image of the interior of the inner tank 34A (i.e., the captured image of the processing liquid) and acquires bubble data indicating the state of bubbles in the processing liquid.

The type and acquisition method of bubble data are not limited. The bubble data typically includes data relating to at least one or more of the number, density, and size of bubbles.

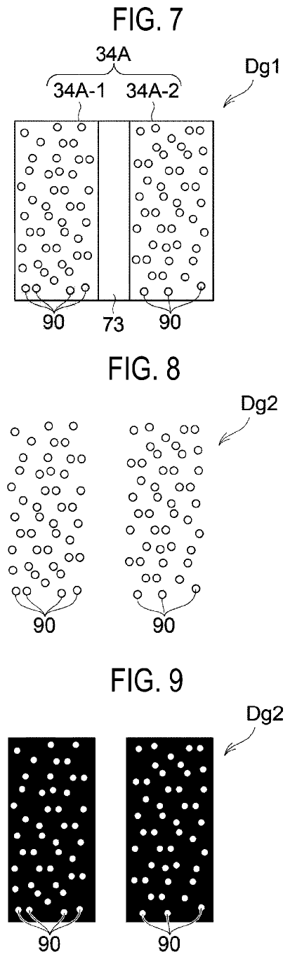

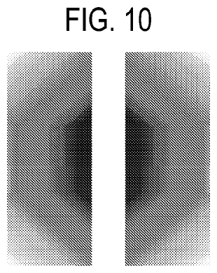

FIG. 7 is a view illustrating an example of a captured image Dg1 acquired by the imager 100. FIG. 8 is a view illustrating an example of a processed image Dg2 acquired by image processing of the captured image Dg1 illustrated in FIG. 7. FIG. 9 is a view illustrating another example of a processed image Dg2 acquired by image processing of the captured image Dg1 illustrated in FIG. 7.

The bubble data acquisitor may acquire a processed image Dg2 (see FIG. 8) by performing image processing for extracting only the image of bubbles 90 from the captured image Dg1 (see FIG. 7). According to the processed image Dg2 illustrated in FIG. 8, it is possible to acquire data on the number, density, and size of bubbles in the processing liquid as bubble data by further performing image processing by the bubble data acquisitor.

The bubble data acquisitor may acquire bubble data based on the gray value of an image by using a characteristic that bubbles appear white in the image.

For example, when the imager 100 acquires a grayscale image as the captured image Dg1 of the interior of the inner tank 34A, the bubble data acquisitor may directly acquire bubble data from the captured image (the grayscale image) sent from the imager 100.

On the other hand, when the imager 100 acquires a color image as the captured image Dg1 of the interior of the inner tank 34A, the bubble data acquisitor may convert the captured image Dg1 (the color image) into a grayscale image and may acquire bubble data from the grayscale image.

Further, the bubble data acquisitor may acquire a processed image Dg2 (see FIG. 9) by performing a binarization process on the captured image Dg1 (see FIG. 7). The white spots in the binarized processed image Dg2 basically represent bubbles 90. Therefore, when the number or area of white spots in the binarized processed image Dg2 is large, the degree of bubbles in the processing liquid is high.

A single image obtained by instantaneously photographing the interior of the inner tank 34A does not necessarily properly reflect the state of bubbles in the processing liquid.

Therefore, the bubble data acquisitor may acquire, as bubble data, representative values (e.g., average values or median values) of data indicating the state of bubbles in the processing liquid obtained from a plurality of images (which may include a plurality of moving image frames) of the interior of the inner tank 34A.

As an example, when the imager 100 acquires a moving image of the interior of the inner tank 34A, the bubble data acquisitor may acquire bubble data based on an average value or median value of bubble state data obtained from each of moving image frames obtained in a certain period of time (e.g., 1 minute).

In addition, the bubble data acquisitor may acquire, as bubble data, data (e.g., image data) created from a plurality of images of the processing liquid inside the inner tank 34A. For example, for each pixel, the bubble data acquisitor may derive representative values (e.g., average values or median values) of respective pixel values of the plurality of images and may acquire, as bubble data, data collectively including the representative values of respective pixels.

FIG. 10 illustrates an example of image data (i.e., bubble data) created from representative values (especially, average values) of respective pixel values (especially, luminance values of respective pixels) of a plurality of images. In FIG. 10, it is illustrated that a spot closer to black has a smaller number of bubbles, and a spot closer to white has a larger number of bubbles.

Even if it is difficult to directly acquire the data of individual bubbles in the processing liquid from a captured image, it is possible to specify the state of bubbles with high accuracy based on bubble data obtained from a set of representative values of respective pixels.

The above-described etching apparatus 1, which is capable of objectively specifying and evaluating the state of bubbles in the processing liquid based on a captured image of a processing liquid, may operate in various modes.

A typical example of the operation of the etching apparatus 1 will be described below.

### First Embodiment

The etching apparatus 1 of the present embodiment adjusts the concentration and temperature of a processing liquid to adjust the boiling state of the processing liquid to a desired state.

FIG. 11 is a functional block diagram illustrating an example of an image processor 101 according to a first embodiment.

The image processor 101 includes a bubble data acquisitor 111, a boiling state determinator 112, and an adjustment amount deriver 113.

The bubble data acquisitor 111 receives an image of the interior of the inner tank 34A acquired by the imager 100 (i.e., an image of the processing liquid), and performs image processing on the image to acquire bubble data (e.g., data about the number, density, or size of bubbles, pixel representative value data, or the like).

Based on the bubble data acquired by the bubble data acquisitor 111, the boiling state determinator 112 determines the boiling state of the processing liquid. Whether or not the boiling state of the processing liquid is appropriate may be determined based on whether or not the bubble data is within a permissible range.

For example, in the case where the bubble data is data relating to the number of bubbles 90, when the number of bubbles 90 indicated by the bubble data is equal to or larger than the lower limit value of the permissible range and equal to or less than the upper limit value of the permissible range, it may be determined that the boiling state of the processing liquid is appropriate. On the other hand, when the number of bubbles 90 indicated by the bubble data is smaller than the lower limit of the permissible range or larger than the upper limit of the permissible range, it may be determined that the boiling state of the processing liquid is not appropriate.

In addition, the boiling state determinator 112 may determine whether or not the boiling state of the processing liquid is appropriate by comparing bubble data with reference data which will be described later. As an example, when the absolute value of a difference between bubble data (e.g., an average gray value or median gray value to be described later) and reference data is smaller than a permissible value, it may be determined that the boiling state of the processing liquid is appropriate.

The adjustment amount deriver 113 derives concentration adjustment data of the processing liquid based on the determination result of the boiling state determinator 112 (i.e., the boiling state of the processing liquid). The adjustment data derived by the adjustment amount deriver 113 is sent to the processing liquid adjuster 102.

The processing liquid adjuster 102 adjusts the concentration of the processing liquid inside the inner tank 34A to a desired concentration based on the adjustment data sent from the adjustment amount deriver 113 (the image processor 101). The processing liquid adjuster 102 of the present example adjusts the flow control valve 40D, the opening and closing valve 40E, the pump 51, and/or the flow regulator 41B to adjust the concentration of the processing liquid inside the inner tank 34A.

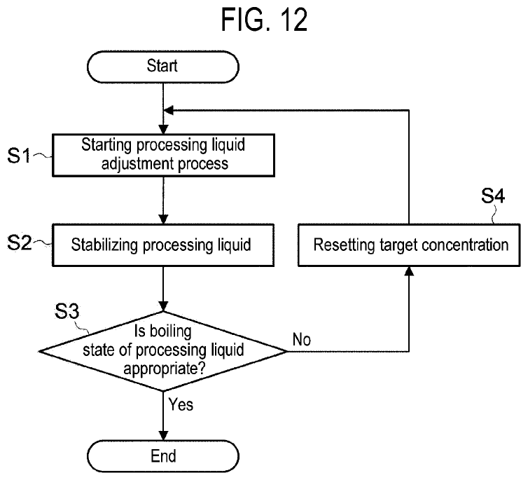

FIG. 12 is a flowchart illustrating an example of a substrate liquid-processing method (especially, a processing liquid adjustment method) according to the first embodiment.

The processing liquid adjustment method described below is performed by appropriately controlling various devices by the controller 7.

In the processing liquid adjustment method of the present example, the flow regulator 60C is controlled by the controller 7, so that the method is performed in a state in which gas (hereinafter, also referred to as “bubbling gas”) is not ejected into the processing liquid from the plurality of ejection ports 60D (see FIGS. 2 to 5) of the gas nozzle 60.

First, the process of adjusting the processing liquid to a certain target concentration and a target temperature (i.e., the processing liquid adjustment process) is started by the processing liquid adjuster 102 under the control of the controller 7 (S1 in FIG. 12). The controller 7 monitors the concentration (e.g., the result of measurement by the phosphoric acid concentration meter 55B) and the temperature (e.g., the result of measurement by a thermometer (not illustrated)) of the processing liquid inside the inner tank 34A and controls the processing liquid adjuster 102 based on the monitoring results, thereby performing the processing liquid adjustment process.

The target concentration and target temperature used in the present step (S1) are set, for example, to the concentration and temperature considered necessary to implement the target boiling state of the processing liquid. The target concentration and target temperature used in the present step (S1) may be automatically set by the etching apparatus 1 (e.g., the controller 7) based on various conditions, or may be manually set by an engineer.

Then, a processing liquid stabilization process is performed to stabilize the processing liquid at the adjusted temperature and concentration (S2). As an example of the processing liquid stabilization process, the above-described processing liquid adjustment process is continuously performed until variations in the temperature and concentration of the processing liquid (i.e., the variation range over a certain period of time) are sufficiently reduced.

Thereafter, the boiling state determinator 112 determines whether or not the boiling state of the processing liquid is appropriate based on the above-described bubble data (S3).

When it is determined that the boiling state of the processing liquid is appropriate (“Yes” in S3), adjustment of the processing liquid is completed.

On the other hand, when it is determined that the boiling state of the processing liquid is not appropriate (“No” in S3), the target concentration is reset by the adjustment amount deriver 113 (S4), and the processing liquid adjustment process is performed based on the reset target concentration (S1 and S2). That is, adjustment data corresponding to the reset target concentration is sent from the adjustment amount deriver 113 to the processing liquid adjuster 102, and the processing liquid adjuster 102 performs the processing liquid adjustment process again based on the adjustment data.

In the present example, the reset target concentration and adjustment data are determined based on a comparison between the bubble data and the permissible range. Specifically, the adjustment amount deriver 113 determines the reset target concentration and adjustment data such that the boiling state of the processing liquid indicated by the bubble data approaches the target boiling state. Specifically, the adjustment amount deriver 113 determines the reset target concentration and the adjustment data such that the difference between the current target concentration and the reset target concentration increases as the deviation of the bubble data from the permissible range increases.

As described above, according to the present embodiment, an image of the processing liquid is acquired by imaging, and the boiling state of the processing liquid is quantified by analyzing the image. As a result, the boiling state (e.g., boiling strength) of the processing liquid can be represented by numerical values derived based on the captured image.

Therefore, the boiling state of the processing liquid can be objectively and accurately grasped based on the numerical values, and the processing liquid can be adjusted to a desired state while completely eliminating device control based on an engineer's subjectivity. As a result, the liquid-processing of substrates 8 can be performed stably and uniformly. In addition, when liquid-processing of substrates 8 is performed by using a plurality of etching apparatuses 1, the liquid-processing of the substrates 8 can be uniformly performed among the etching apparatuses 1.

In addition, imaging of the processing liquid, acquisition of bubble data by image analysis, determination of the boiling state of the processing liquid based on the bubble data, and derivation of adjustment data used for adjusting the concentration of the processing liquid are performed mechanically. Therefore, by automating a series of these processes, the burden on engineers can be reduced. Especially, in the present embodiment, since the concentration of the processing liquid is also mechanically adjusted based on the adjustment data, the processing liquid inside the inner tank 34A is automatically adjusted to a desired state without any manual intervention.

When visually identifying the state of bubbles in the processing liquid after changing the concentration and temperature of the processing liquid, it is necessary for an engineer to wait for the state of the processing liquid to stabilize before identifying the state of the bubbles in the processing liquid. It may take a long time (e.g., an hour or more) for the processing liquid to stabilize, and engineers may be constrained for a long time to visually identify the state of bubbles in the processing liquid.

On the other hand, according to the present embodiment, even if it takes a long time for the processing liquid to stabilize after changing the concentration and temperature of the processing liquid, engineers are rarely or never constrained.

### Second Embodiment

In the present embodiment, the same reference numerals are given to the same or corresponding elements as in the above-described first embodiment, and a detailed description thereof will be omitted.

In the present embodiment, the state of the gas (bubbling bubbles), which is sent from the gas nozzle 60 (a bubbler) to the processing liquid inside the inner tank 34A, in the processing liquid is evaluated, and notification is made according to the evaluation.

In a phosphoric acid etching process, regrowth can be suppressed and phosphoric acid etching can be promoted by appropriately releasing bubbling bubbles (i.e., bubbling) into the processing liquid. However, the state of bubbling may vary due to clogging of the gas nozzle 60 or variation in the diameter of the flow path. When the bubbling state varies, the regrowth suppression performance and etching performance of the etching apparatus 1 vary. Therefore, from the viewpoint of ensuring the regrowth suppression performance and etching performance of the etching apparatus 1, it is preferable to detect an abnormality in the bubbling state.

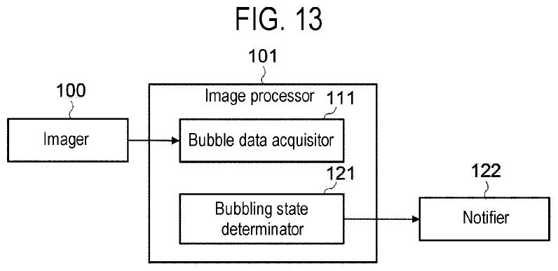

FIG. 13 is a functional block diagram illustrating an example of an image processor 101 according to a second embodiment.

The image processor 101 includes a bubble data acquisitor 111 and a bubbling state determinator 121.

The bubble data acquisitor 111 acquires bubble data by receiving an image of the interior of the inner tank 34A (i.e., an image of the processing liquid) acquired by the imager 100 and performing image-processing of the image.

The bubble data acquisitor 111 of the present example derives, for each pixel, the representative values of respective pixel values of a plurality of images and acquires, as bubble data, image data created by a set of representative values of respective pixels (see FIG. 10 described above). Bubble data (image data) acquired based on the brightness values of respective pixels represents the state of bubbles in the processing liquid by image contrast, and the spots with many bubbles in the processing liquid are expressed whitish. As a result, even if it is difficult to directly determine the number, density, and size of bubbles in the processing liquid from the image data acquired by the imager 100, it becomes possible to appropriately determine the state of the bubbles in the processing liquid.

The bubbling state determinator 121 determines the state of the bubbling bubbles, which are sent from the gas nozzle 60 to the processing liquid inside the inner tank 34A, in the processing liquid based on the bubble data. The bubbling state determinator 121 of the present example determines the state of the bubbling bubbles in the processing liquid by comparing the bubble data with reference data.

The reference data used here is data based on the reference state of the bubbling bubbles, and is stored by the bubbling state determinator 121. Typically, the bubble data (see FIG. 10) when the state of the bubbling bubble in the processing liquid is normal is used as the reference data. In this case, the bubbling state determinator 121 may calculate difference values (hereinafter, also referred to as “pixel difference values”) between pixel values of bubble data obtained from a captured image of the processing liquid to be evaluated and pixel values of the reference data.

The bubbling state determinator 121 may determine the state of the bubbling bubbles in the processing liquid depending on the pixel difference values of respective pixels. That is, the bubbling state determinator 121 may determine the state of bubbling bubbles in the processing liquid based on the number and/or distribution of pixels having large pixel difference values (e.g., pixels exhibiting pixel difference values greater than a predetermined value). The bubbling state determinator 121 may determine that the state of the bubbling bubbles in the processing liquid is abnormal when the number or density of pixels with large pixel difference values is greater than a predetermined value.

In particular, the bubbling state determinator 121 of the present example determines the state of the bubbling bubbles with reference to the entire range of the processing liquid and the state of the bubbling bubbles with reference to the local range of the processing liquid based on the bubble data. As a result, when the bubbling state determinator 121 may acquire information on factors that may cause an abnormality when determining that the abnormality has occurred in the state of the bubbling bubbles.

For example, when pixels having large pixel difference values are present over an entire captured image (especially, the image of the processing liquid), it may be considered that the state of the bubbling bubbles is abnormal over the entire processing liquid. Therefore, it is considered that there is a possibility that an abnormality has occurred in a factor that may affect the entire processing liquid. For example, it is considered that there is a possibility that an abnormality has occurred in the flow rate of the gas ejected from the gas nozzle 60 into the processing liquid, the concentration of the processing liquid, and/or the temperature of the processing liquid.

Here, an “average gray value” and a “median gray value” are gray values derived by image analysis, which are the average and median gray values of respective pixels in the entire image, may indicate the state of the bubbles in the processing liquid. In the present example, the black pixel value is the minimum value (e.g., zero (0)), and the white pixel value is the maximum value. Therefore, as the average gray value and the median gray value increase, the number of bubbles (gas-liquid interfaces) present in the processing liquid increases, and as the average gray value and median gray value decrease, the number of bubbles present in the processing liquid decreases.

The average gray value and the median gray value of the image of the processing liquid captured by the imager 100 in the state in which bubbling bubbles are ejected from the gas nozzle 60 into the processing liquid vary depending on the flow rate of the gas, the temperature of the processing liquid, and the concentration of the processing liquid. That is, the average gray value and the median gray value may be expressed by functions f and f using the flow rate of the gas, the temperature of the processing liquid, and the concentration of the processing liquid as variables, as follows.

Average gray value=f(a flow rate of a gas, a temperature of a processing liquid, a concentration of the processing liquid)

Median gray value=f(a flow rate of a gas, a temperature of a processing liquid, a concentration of the processing liquid)

The functions f and f of the average gray value and the median gray value may be modeled in various forms such as a linear expression, a quadratic expression, a cubic or higher expression, an exponential functions, and the like, and may be expressed, for example, by the following multidimensional linear expression.

Average gray value=α+β1 flow rate of the gas+β2 temperature of the processing liquid+β3 concentration of the processing liquid

Median gray value=α′+β1′ flow rate of the gas+β2′ temperature of the processing liquid+β3′ concentration of the processing liquid

In the above formula for the average gray value and the median gray value, “a” and “a” correspond to gray values in the state in which no bubbles (including bubbling bubbles and bubbles caused by boiling of the processing liquid) are generated in the processing liquid. Therefore, gradation information (e.g., information such as a background) reflected in the captured image due to the hardware configuration of the apparatus is reflected in “α” and “α”.

“β1” to “β3” and “β1” to “β3” are values representing the degree of influence of the flow rate of the gas, the temperature of the processing liquid, and the concentration of the processing liquid in which the values are determined depending on the specific configuration of the etching apparatus 1.

“Flow rate of a gas” is the flow rate of the gas (inert gas in the present example) ejected from the gas nozzle 60 to the processing liquid (i.e., the number of bubbling bubbles ejected per unit time).

“Temperature of a processing liquid” is the temperature of the phosphoric acid aqueous solution in the inner tank 34A in the present example.

“Concentration of a processing liquid” is the concentration of the phosphoric acid aqueous solution in the inner tank 34A in the present example.

According to the above model formulas, the average gray value and the median gray value increase as the flow rate of the gas ejected from the gas nozzle 60 to the processing liquid increases. In addition, as the temperature of the processing liquid increases, the average gray value and the median gray value increase. On the other hand, as the concentration of the processing liquid increases, the average gray value and the median gray value decrease.

Thus, from the above model formulas, it can be seen that the flow rate of the bubbling bubbles ejected from the gas nozzle 60 into the processing liquid, the concentration of the processing liquid, and the temperature of the processing liquid are factors that may affect the entire processing liquid.

On the other hand, when it is determined that there is an abnormality in the state of the bubbling bubbles only in a local area of the processing liquid, it is considered that there is a possibility that an abnormality has occurred in a factor that may affect only such a local area.

In the captured image Dg1 of the present example, as illustrated in FIG. 7, the inner tank 34A is separated into two portions (i.e., a first inner tank portion 34A-1 and a second inner tank portion 34A-2) via the cover 73 and is photographed. When a large number of pixels having large pixel difference values are present only in one of the first inner tank portion 34A-1 and the second inner tank portion 34A-2 in the bubble data and few or none are present in the other inner tank portion, it is considered that there is a possibility that an abnormality has occurred in a factor that affect only one of the inner tank portions. Specifically, it is considered that there is a possibility that local clogging or breakage of the gas nozzle 60 present only in one inner tank portion, shortage of the gas flow rate in the gas nozzle 60 present only in one inner tank portion, breakage of the LFN nozzle, and/or the like has occurred.

The determination result of the bubbling state determinator 121 thus obtained is sent to a notifier 122 (see FIG. 13).

The notifier 122 performs a notification process based on the determination result of the bubbling state determinator 121. The specific contents of the notification process and the notification method are not limited.

The notifier 122 may, for example, perform a notification process of notifying an engineer that the bubbling bubbles in the processing liquid are in a normal and/or abnormal state via audio or visual display. The notification information to be notified to the engineer includes information on the presence or absence of an abnormality in the bubbling state, information on factors that may cause an abnormality (e.g., information on a device that may have a problem), and other information. In addition, when there is an abnormality in the state of the bubbling bubbles in the processing liquid, the notification information may include information for prompting the engineer to perform maintenance.

The notifier 122 may perform the notification process by storing data (which may include image data) indicating that the state of bubbling bubbles in the processing liquid is normal and/or abnormal in a storage (e.g., the storage medium 38 illustrated in FIG. 1). For example, when there is an abnormality in the state of the bubbling bubbles in the processing liquid, the notifier 122 may associate the identification data of the substrates 8 that have undergone the liquid-processing by using the processing liquid in such an abnormal state with abnormality flag data, and may store the identification data and the abnormality flag data in the storage. The abnormality flag data stored in the storage in this manner may be appropriately read and used for subsequent processing.

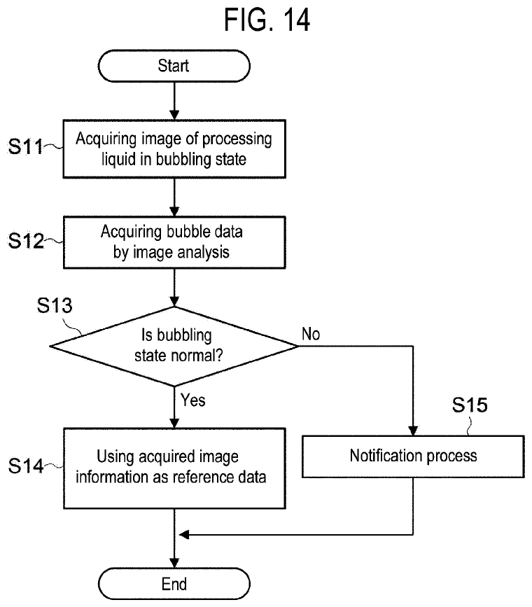

FIG. 14 is a flowchart illustrating an example of a substrate liquid-processing method (especially, a bubbling state determination method) according to the second embodiment.

First, an image of the processing liquid inside the inner tank 34A is acquired by the imager 100 in a state in which bubbling bubbles are ejected from the gas nozzle 60 into the processing liquid inside the inner tank 34A (i.e., in a bubbling state) (S11 in FIG. 14).

In the present example, image-capturing is performed by the imager 100 in a state in which bubbles caused by boiling of the processing liquid (i.e., boiling gas of the processing liquid (which may also be referred to as “boiling bubbles” below)) are not generated. Therefore, the bubbles captured in the image acquired by the imager 100 are basically bubbling bubbles ejected from the gas nozzle 60. Therefore, according to the bubbling state determination method of the present example, the state of the bubbling bubbles ejected from the gas nozzle 60 into the processing liquid (e.g., the amount and unevenness of the bubbling bubbles) can be accurately determined.

Acquisition of a captured image by the imager 100 is performed in a state in which the processing liquid is not boiling in the present example, but may be performed in a state in which the processing liquid is boiling and no boiling bubbles that can be imaged are generated.

The image of the processing liquid acquired by the imager 100 is sent to the bubble data acquisitor 111.

Then, the bubble data acquisitor 111 acquires bubble data by performing image analysis on the image sent from the imager 100 (S12).

Then, the bubbling state determinator 121 determines whether or not the bubbling state is normal based on the bubble data (S13).

When it is determined that the bubbling state is normal (“Yes” in S13), the bubbling state determinator 121 uses the image acquired by the imager 100 as reference data held by itself (S14).

In the present step (S14), a specific method of using the image currently acquired by the imager 100 as reference data is not limited. For example, the bubbling state determinator 121 may use the image acquired this time as reference data for subsequent processes (i.e., processes using images acquired by the imager 100 from the next time onward). Alternatively, the bubbling state determinator 121 may perform a reference data update process (i.e., a reference data correction process) by using the image acquired this time.

On the other hand, when it is determined that the bubbling state is abnormal (“No” in S13), the above-described notification process is performed by the notifier 122 (S15). This allows an engineer to recognize an abnormality in the bubbling state and to timely consider the need for maintenance.

As described above, according to the present embodiment, an image of the processing liquid is acquired by imaging, and the bubbling state of the processing liquid is quantified by analyzing the image. As a result, the bubbling state of the processing liquid (e.g., the amount or distribution of bubbling bubbles) may be represented by numerical values derived based on the captured image.

Therefore, the bubbling state of the processing liquid can be objectively and accurately grasped based on the numerical values, and the bubbling state can be adjusted to a desired state. As a result, the liquid-processing of substrates 8 can be performed stably and uniformly.

In addition, by using the highly accurate determination result of the bubbling state for detection of a device abnormality, the occurrence of the device abnormality can be detected in a timely manner.

Furthermore, by using the captured image of the processing liquid in which the bubbling state is determined to be normal as the reference data, it is possible to improve the determination accuracy of the bubbling state.

### Third Embodiment

In the present embodiment, the same reference numerals are given to the same or corresponding elements as in the above-described first embodiment and second embodiment, and a detailed description thereof will be omitted.

In the present embodiment, the state of bubbling bubbles sent from the gas nozzle 60 to the processing liquid is evaluated, and the number of bubbling bubbles sent from the gas nozzle 60 to the processing liquid is adjusted depending on the evaluation to optimize the bubbling state.

In general, the boiling point of the processing liquid changes depending on the concentration of the processing liquid and the pressure (environmental pressure (e.g., atmospheric pressure)) applied to the processing liquid. Therefore, when bubbles caused due to the boiling of the processing liquid (i.e., boiling bubbles) are actively generated during liquid-processing, the state of the boiling bubbles in the processing liquid changes depending on the environmental pressure.

When the state of the bubbles in the processing liquid is changed, the regrowth suppression performance and etching performance of the etching apparatus 1 may change, the liquid-processing of the substrates 8 may become unstable, and liquid-processing of substrates 8 may not be performed appropriately. In order to stabilize the state of boiling bubbles in the processing liquid, it is necessary to keep the boiling state of the processing liquid constant.

For example, by changing the concentration of the processing liquid depending on the environmental pressure, it is possible to keep the boiling state of the processing liquid constant. However, when the concentration of the processing liquid changes, the liquid processing state (e.g., etching rate) of the substrates 8 may change, and the liquid processing state of the substrates 8 may vary.

In view of such a circumstance, in the present embodiment, the bubbling state of the processing liquid at the time of performing liquid-processing is optimized by adjusting the flow rate of bubbling bubbles ejected from the gas nozzle 60 into the processing liquid without changing the concentration of the processing liquid.

In the examples to be described below, image-capturing by the imager 100 and liquid-processing of substrates 8 are performed in a state in which the processing liquid has a temperature and a concentration at which boiling bubbles do not occur even when any conceivable change in environmental pressure occurs. Therefore, the bubbling state of the processing liquid during the image-capturing by the imager 100 and the liquid-processing of the substrates 8 is basically caused by bubbling bubbles ejected into the processing liquid from the gas nozzle 60.

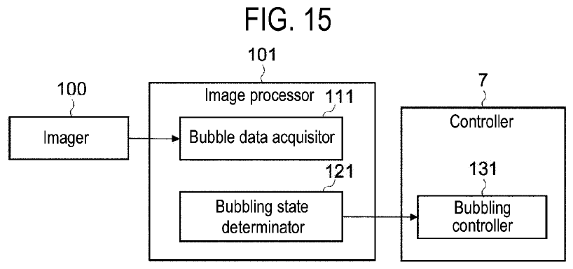

FIG. 15 is a functional block diagram illustrating an example of an image processor 101 according to a third embodiment.

The image processor 101 includes a bubble data acquisitor 111 and a bubbling state determinator 121. The bubble data acquisitor 111 and the bubbling state determinator 121 function in the same manner as in the second embodiment described above.

That is, the bubble data acquisitor 111 acquires bubble data by receiving an image of the interior of the inner tank 34A (i.e., an image of the processing liquid) acquired by the imager 100 and performing image-processing of the image.

The bubbling state determinator 121 determines the state of the bubbling bubbles, which are sent from the gas nozzle 60 (the bubbler) to the processing liquid inside the inner tank 34A, in the processing liquid based on the bubble data. Specifically, the bubbling state determinator 121 of the present example determines the state of the bubbling bubbles in the processing liquid by comparing the bubble data with reference data.

The bubbling state determinator 121 of the present embodiment sends the determination result to a bubbling controller 131. The determination result sent from the bubbling state determinator 121 to the bubbling controller 131 includes information about a difference between the current state of bubbling bubbles and the desired state of bubbling bubbles (i.e., information about a difference between the current bubble data and the reference data).

The bubbling controller 131 illustrated in FIG. 15 is provided as a part of the controller 7 and controls the bubbler based on the determination result of the bubbling state determinator. The bubbling controller 131 may be provided separately from the controller 7. In this case, the bubbling controller 131 may be controlled by the controller 7.

The bubbler includes one or more devices that contribute to supplying bubbling bubbles to the processing liquid inside the inner tank 34A. The bubbler of the present example includes the gas nozzle 60, the pipe 60A, the gas source 60B, and the flow regulator 60° C. illustrated in FIGS. 2 and 3, etc. The bubbling controller 131 controls the flow regulator 60C to adjust the number of bubbling bubbles ejected from the ejection ports 60D of the gas nozzle 60 into the processing liquid (i.e., the flow rate of the bubbling bubbles in the gas nozzle 60).

The bubbling controller 131 of the present example controls the flow regulator 60C to regulate the flow rate of the inert gas supplied toward the gas nozzle 60 so as to implement a desired bubbling state. Specifically, the bubbling controller 131 controls the flow regulator 60C based on the “information about the difference between the current state of bubbling bubbles and the desired state of bubbling bubbles” sent from the bubbling state determinator 121. As a result, an appropriate number of bubbling bubbles are ejected from the gas nozzle 60 into the processing liquid, and the state of the bubbling bubbles in the processing liquid is adjusted to a desired state.

For example, the bubbling controller 131 may determine the control amount of the flow regulator 60C by comparing the determination result of the bubbling state determinator 121 with the reference model, and may control the flow regulator 60C based on the control amount. The reference model is determined based on, for example, the number of bubbling bubbles supplied into the processing liquid, the concentration of the processing liquid, and the temperature of the processing liquid. As an example, the reference model may be determined based on the model formula of the above-described average gray value or median gray value.

Alternatively, the bubbling controller 131 may determine the control amount of the flow regulator 60C by comparing the determination result of the bubbling state determinator 121 with a reference table, and may control the flow regulator 60C based on the control amount. In the reference table, the states of the bubbling bubbles in a processing liquid are associated with the amounts of bubbling bubbles supplied into the processing liquid.

With the etching apparatus 1 of the present embodiment, even if the environmental pressure varies, the ejection state of bubbling bubbles from the gas nozzle 60 to the processing liquid is adjusted so that the bubbling state of the processing liquid can be maintained in a desired state. By maintaining the desired bubbling state without changing the concentration of the processing liquid in this way, the liquid-processing of substrates 8 can be stably performed.

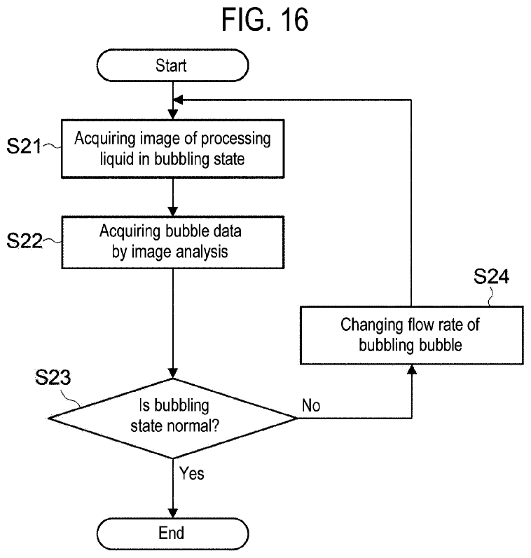

FIG. 16 is a flowchart illustrating an example of a substrate liquid-processing method (especially, a bubbling state adjustment method) according to the third embodiment.

In the present example as well, similarly to the substrate liquid processing method (second embodiment) illustrated in FIG. 14, an image of the processing liquid in the bubbling state is acquired by the imager 100 (S21 in FIG. 16), and bubble data is acquired by image analysis performed by the bubble data acquisitor 111 (S22). In the present example, the bubble data acquired by the bubble data acquisitor 111 is based on gray values.

Then, the bubbling state determinator 121 determines whether or not the bubbling state is normal based on the bubble data (S23). When it is determined that the bubbling state is normal (“Yes” in S23), the adjustment of the bubbling state of the processing liquid is completed.

On the other hand, when it is determined that the bubbling state is abnormal (“No” in S23), the bubbling controller 131 controls the bubbler (the flow regulator 60C) as described above, and the flow rate of bubbling bubbles is changed such that the bubbling state approaches a desired state (S24). After the flow rate of the bubbling bubbles is changed in this way, the adjustment of the bubbling state is performed by repeating the above-described steps S21 to S23.

The above-described adjustment of bubbling state may be implemented in various adjustment modes. A typical example of the mode of adjusting the bubbling state will be described below.

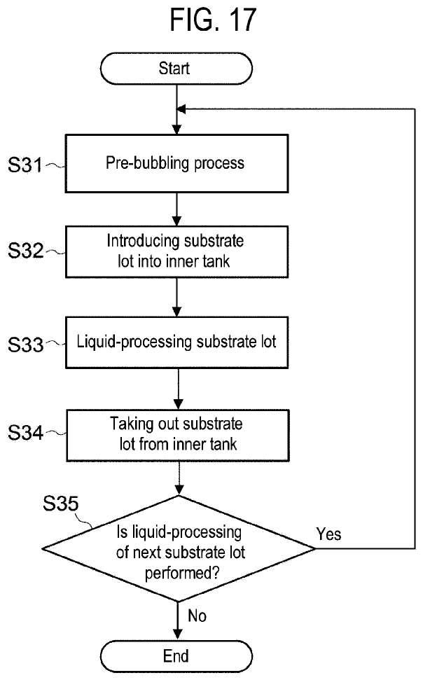

FIG. 17 is a flowchart illustrating an example of a flow of liquid-processing of substrates 8.

In the example illustrated in FIG. 17, bubbling bubbles are ejected from the gas nozzle 60 before the substrates 8 are introduced into the inner tank 34A (a pre-bubbling process (S31 in FIG. 17)).

Thereafter, the substrates 8 are introduced into the inner tank 34A (S32). In the present example, as described above, a plurality of substrates 8 (substrate lot) are introduced into the inner tank 34A at once.

Thereafter, liquid-processing (etching) of the substrate lot is performed in the inner tank 34A (S33).

Thereafter, the substrate lot for which the liquid-processing has been completed is taken out from the inner tank 34A (S34).

Then, when liquid-processing of the next substrate lot is necessary (“Yes” in S35), the above-described steps S31 to S34 are repeated.

On the other hand, when the liquid-processing of the next substrate lot is not necessary (“No” in S35), the liquid-processing of the substrates 8 is completed.

In the above-described substrate liquid-processing method illustrated in FIG. 17, the bubbling state may be adjusted as follows.

### [First Bubbling State Adjustment Mode]

All of the imaging of a processing liquid, the acquisition of bubble data, the determination of a bubbling state, and the control of the bubbler may be repeatedly and continuously performed while the liquid-processing of substrates 8 (substrate lot) is being performed (S33).

In the present mode, the imager 100 acquires a captured image of the processing liquid in a state in which the substrates 8 (substrate lot) are immersed in the processing liquid and bubbling bubbles are ejected from the gas nozzle 60 into the processing liquid.

The bubble data acquisitor 111 acquires bubble data by performing image processing on the image acquired in the state in which the substrates 8 (substrate lot) are immersed in the processing liquid, and the bubbling state determinator 121 determines the bubbling state based on the bubble data.

Based on the determination result of the bubbling state determinator 121, the bubbling controller 131 controls the bubbler (the flow regulator 60C) to supply an appropriate number of bubbling bubbles into the processing liquid in which the substrates 8 (substrate lot) are immersed.

According to the present mode, since a series of processes from imaging of a processing liquid to controlling of the bubbler (adjustment of the sent number of bubbling bubbles) is performed for each substrate lot, the processing liquid can be adjusted to a bubbling state that is individually adapted to the substrate lot.

### [Second Bubbling State Adjustment Mode]

In this mode, while the liquid-processing of a first substrate lot is being performed (S33), a captured image of the processing liquid is acquired by the imager 100, and acquisition of bubble data and determination of a bubbling state are performed based on the captured image.

Based on the determination result of the bubbling state thus obtained (i.e., the determination result of the bubbling state based on the captured image during the liquid-processing of the first substrate lot), the bubbler is controlled for liquid-processing of the second substrate lot (second substrates). That is, the bubbling performed between the pre-bubbling process (S31) for the liquid-processing of the second substrate lot and the liquid-processing of the second substrate lot (S33) is performed based on the determination result of the bubbling state during the liquid-processing of the first substrate lot (S33).

As described above, according to this mode, the bubble data acquisitor 111 acquires bubble data by performing image processing on an image acquired in the state in which the first substrate lot (first substrates) is immersed in the processing liquid.

Based on the determination result of the bubbling state determinator 121, the bubbling controller 131 controls the bubbler to supply a gas into the processing liquid in which the second substrate lot (second substrates) to be introduced into the inner tank 34A after the first substrate lot is taken out from the inner tank 34A is immersed.

As described above, in the present mode, the determination result of the bubbling state in the preceding liquid processing of the substrates (first substrates) 8 is used as feedback in the subsequent liquid processing of the substrates (second substrates) 8.

### [Third Bubbling State Adjustment Mode]

In the present mode, in the pre-bubbling process (S31), a captured image of a processing liquid is acquired by the imager 100, and acquisition of bubble data and determination of a bubbling state are performed based on the captured image. Then, in the subsequent liquid-processing of the substrate lot (S33), the bubbler is controlled based on the determination result of the bubbling state.

In the present mode, the imager 100 acquires a captured image of the processing liquid in which bubbling bubbles are ejected in the state in which the substrates 8 are not immersed in the processing liquid.

The bubble data acquisitor 111 acquires bubble data by performing image processing on the captured image acquired in the state in which the substrate 8 is not immersed in the processing liquid.

The bubbling controller 131 controls the bubbler to supply bubbling bubbles into the processing liquid in which the substrates 8 are immersed, based on the determination results of the bubbling state determinator 121 derived from the bubble data.

Normally, there is a short time between the timing at which the pre-bubbling process (S31) is performed and the timing at which the liquid-processing of the substrate lot (S33) is performed, and the environmental pressure of the processing liquid does not change abruptly during this short period of time. Therefore, in this mode, there is substantially almost no or no problem caused by the difference between the step of imaging the processing liquid and determining the bubbling state and the step of controlling the bubbler.

### Fourth Embodiment

In the present embodiment, the same reference numerals are given to the same or corresponding elements as in the above-described first to third embodiments, and a detailed description thereof will be omitted.

In the present embodiment, the state of bubbling bubbles sent from the gas nozzle 60 to the processing liquid is evaluated, and the state of supplying the bubbling bubbles from the gas nozzle 60 is adjusted depending on the evaluation, thereby improving the balance of liquid-processing on individual substrates 8.

Even individual substrates 8 are not necessarily uniformly subjected to liquid-processing, and the degree of liquid-processing may vary depending on the locations of surfaces to be processed on the substrates 8. The main cause of such variations in liquid-processing for individual substrates 8 is considered to be a fixed one originating from the configuration of the etching apparatus 1.

In fact, as a result of evaluating the processed surfaces of the substrates 8 after the liquid-processing by the etching apparatus 1, the state of processing unevenness of the individual substrates 8 was similar among the substrates 8, and in particular, the substrates 8 subjected to the liquid-processing at the same position in the inner tank 34A had very similar processing unevenness. From this result as well, it can be seen that, as the cause of variations in the liquid-processing of the individual substrates 8 (i.e., uneven processing), factors originating from the configuration of the etching apparatus 1 are dominant, and variations in the liquid-processing of each of the substrates 8 are reproducible.

When liquid-processing is performed on the substrates 8 while ejecting bubbling bubbles from the gas nozzle 60, the bubbling state of the processing liquid contributes to variation in the liquid-processing of the substrates 8. In light of the movement of bubbles in the processing liquid in the height direction (especially, upward direction), variations in the horizontal direction of the liquid-processing of the individual substrates 8 can be improved by adjusting the ejection state of bubbling bubbles from a plurality of gas nozzles 60 arranged in the horizontal direction.

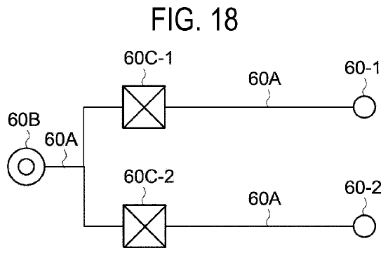

FIG. 18 is a view illustrating an example of a bubbler according to a fourth embodiment.

In the present embodiment, a first bubbler and a second bubbler are provided to supply a gas from different positions to the processing liquid inside the inner tank 34A in the horizontal direction.

The bubblers illustrated in FIG. 18 include a gas source 60B, and a first flow regulator 60C-1, a second flow regulator 60C-2, a first gas nozzle 60-1, and a second gas nozzle 60-2, which are installed in a pipe 60A extending from the gas source 60B. One pipe 60A extending from the gas source 60B is branched into two pipes 60A on the way. One branched pipe 60A is provided with the first flow regulator 60C-1 and the first gas nozzle 60-1, and the other branched pipe 60A is provided with the second flow regulator 60C-2 and the second gas nozzle 60-2.

In the apparatus configuration illustrated in FIG. 18, the first bubbler includes the pipe 60A, the gas source 60B, the first flow regulator 60C-1, and the first gas nozzle 60-1. The second bubbler includes the pipe 60A, the gas source 60B, the second flow regulator 60C-2, and the second gas nozzle 60-2.

As illustrated in FIG. 3, the first gas nozzle 60-1 and the second gas nozzle 60-2 are disposed at different positions in the horizontal direction (the Y direction) inside the inner tank 34A. In the example illustrated in FIG. 3, the first gas nozzle 60-1 is located in the first inner tank portion 34A-1, and most of the bubbling bubbles ejected from the first gas nozzle 60-1 move in the first inner tank portion 34A-1. On the other hand, the second gas nozzle 60-2 is located in the second inner tank portion 34A-2, and most of the bubbling bubbles ejected from the second gas nozzle 60-2 move in the second inner tank portion 34A-2.

Thus, in the interior of the inner tank 34A, the spot where the first gas nozzle 60-1 (the first bubbler) ejects gas and the spot where the second gas nozzle 60-2 (the second bubbler) ejects gas are horizontally opposite to each other with reference to the position where the substrates 8 are disposed.

Although, in FIG. 3, etc., two gas nozzles 60 are provided inside the inner tank 34A, the number of gas nozzles 60 is not limited, and any number of two or more gas nozzles 60 may be arranged in the horizontal direction (particularly in the Y direction). In this case, preferably, one or more gas nozzles 60 are assigned to the first inner tank portion 34A-1 and one or more gas nozzles 60 are assigned to the second inner tank portion 34A-2.

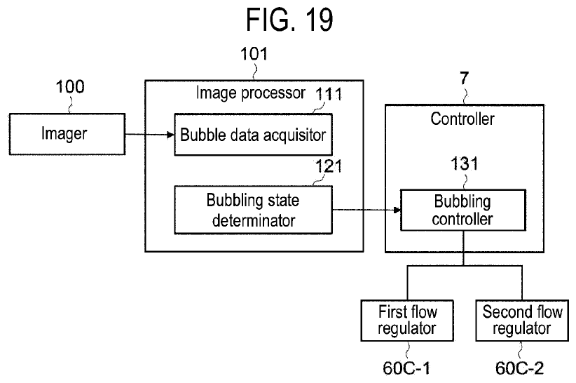

FIG. 19 is a functional block diagram illustrating an example of an image processor 101 according to a fourth embodiment.

The image processor 101 of the present example has the same configuration as the image processor 101 (see FIG. 15) according to the above-described third embodiment and includes a bubble data acquisitor 111 and a bubbling state determinator 121.

The bubbling state determinator 121 determines the state of bubbling bubbles in the processing liquid based on the bubble data acquired by the bubble data acquisitor 111 and sends the determination result to the bubbling controller 131.

Based on the determination result of the bubbling state determinator 121, the bubbling controller 131 of the present embodiment controls the first flow regulator 60C-1 (the first bubbler) and the second flow regulator 60C-2 (the second bubbler).

The determination of the bubbling state by the bubbling state determinator 121 and the control by the bubbling controller 131 are basically performed in the same manner as in the above-described second embodiment. That is, the bubbling state determinator 121 determines the state of bubbling bubbles in the processing liquid by comparing the bubble data acquired by the bubble data acquisitor 111 with the reference data. The bubbling state determinator 121 acquires information about the difference between the current state of bubbling bubbles and the desired state of bubbling bubbles by comparing the bubble data with the reference data.

The reference data used in the present embodiment is bubble data (see FIG. 10) when the bubbling bubbles in the processing liquid are in a normal state. In particular, the bubble data when there are little or no “variations in liquid-processing of the substrates 8 in the horizontal direction” originating from the configuration of the etching apparatus 1 may be used as the reference data.

When the bubble data and the reference data are configured with gray value maps (see FIG. 10), a difference gray value between the bubble data and the reference data may be acquired as the “information about the difference between the current state of bubbling bubbles and the desired state of bubbling bubbles”.

The bubbling controller 131 controls the first flow regulator 60C-1 and the second flow regulator 60C-2 based on the “information about a difference between the current state of bubbling bubbles and the desired state of bubbling bubbles” sent from the bubbling state determinator 121.

As described above, the bubbling state determinator 121 determines whether or not the state of bubbling bubbles in the processing liquid is normal from the viewpoint of suppressing variations of liquid-processing in the horizontal direction. The bubbling controller 131 controls the first flow regulator 60C-1 and the second flow regulator 60C-2 so as to suppress variations in liquid-processing in the horizontal direction.

As described above, according to the present embodiment, the balance of the ejection flow rate of bubbling bubbles is optimized between the first bubbler and the second bubbler so that the uniformity of liquid-processing on individual substrates 8 can be improved.

### [Modifications]

In the above-described embodiments, the processing liquid is an aqueous phosphoric acid solution, but it is not limited thereto. For example, a processing liquid obtained by mixing an additive such as acetic acid to SCI or an aqueous phosphoric acid solution may be used. In addition, in the above-described embodiments, a film to be etched is a silicon nitride film, but the film is not limited thereto. Another film may be the film to be etched. The substrates are not limited to semiconductor wafers, and may be substrates made of other materials such as glass and ceramic.

It is to be noted that the embodiments and modifications disclosed herein are merely exemplary in all respects and are not construed limitedly. The above-described embodiments and modifications can be omitted, substituted, and modified in various ways without departing from the scope and spirit of the appended claims. For example, the above-described embodiments and modifications may be partially or wholly combined, and embodiments other than those described above may be partially or wholly combined with the above-described embodiments or modifications.

In addition, the technical category that implements the above-described technical ideas is not limited. For example, the above-described substrate liquid-processing apparatus may be applied to other apparatuses. In addition, the above-described technical ideas may be implemented by computer programs that allow a computer to execute one or more procedures (steps) included in the above-described substrate liquid processing method. Furthermore, the above-described technical ideas may be implemented by a computer-readable non-transitory recording medium in which such computer programs are recorded.

1. A substrate liquid-processing apparatus comprising:
a processing tank storing a processing liquid for liquid-processing of a substrate within an inside;
an imager configured to acquire an image of the processing liquid of the inside of the processing tank; and
an image processor comprising a bubble data acquisitor configured to perform image processing on the image and to acquire bubble data representing a state of bubbles in the processing liquid.

2. The substrate liquid-processing apparatus of claim 1, wherein the image processor comprises a boiling state determinator configured to determine a boiling state of the processing liquid based on the bubble data.

3. The substrate liquid-processing apparatus of claim 2, further comprising:
an adjustment amount deriver configured to derive adjustment data for a concentration of the processing liquid based on a determination result of the boiling state determinator.

4. The substrate liquid-processing apparatus of claim 1, further comprising:
a bubbler configured to supply a gas to the processing liquid of the inside of the processing tank;
a notifier configured to perform a notification process,
wherein the image processor comprises a bubbling state determinator configured to determine a state of the gas in the processing liquid based on the bubble data, and
the notifier is further configured to perform the notification process based on a determination result of the bubbling state determinator.

5. The substrate liquid-processing apparatus of claim 4, wherein the bubbling state determinator is further configured to determine the state of the gas in the processing liquid by comparing the bubble data with reference data based on a reference state of the gas in the processing liquid.

6. The substrate liquid-processing apparatus of claim 4 or 5, wherein the bubbling state determinator is further configured to determine, based on the bubble data, a gas state with reference to an entire range of the processing liquid and a gas state with reference to a local range of the processing liquid.

7. The substrate liquid-processing apparatus of claim 1, further comprising:
a bubbler configured to supply a gas to the processing liquid of the inside of the processing tank; and
a bubbling controller configured to control the bubbler,
wherein the image processor comprises a bubbling state determinator configured to determine a state of the gas in the processing liquid based on the bubble data, and
the bubbling controller is further configured to control the bubbler based on a determination result of the bubbling state determinator.

8. The substrate liquid-processing apparatus of claim 7, wherein the bubble data acquisitor is further configured to acquire the bubble data by performing the image processing of the image acquired in a state in which the substrate is not immersed in the processing liquid, and
the bubbling controller is further configured to control the bubbler to supply the gas into the processing liquid in which the substrate is immersed, based on the determination result of the bubbling state determinator.

9. The substrate liquid-processing apparatus of claim 7, wherein the bubble data acquisitor is further configured to acquire the bubble data by performing the image processing of the image acquired in a state in which a first substrate is immersed in the processing liquid, and
the bubbling controller is further configured to control, based on the determination result of the bubbling state determinator, the bubbler to supply the gas in the processing liquid in which a second substrate introduced into the processing tank after the first substrate is taken out from the processing tank is immersed in the processing liquid.

10. The substrate liquid-processing apparatus of claim 7, wherein the bubble data acquisitor is further configured to acquire the bubble data by performing the image processing of the image acquired in a state in which the substrate is immersed in the processing liquid, and
the bubbling controller is further configured to control the bubbler to supply the gas into the processing liquid in which the substrate is immersed, based on the determination result of the bubbling state determinator.

11. The substrate liquid-processing apparatus of claim 1, further comprising:
a first bubbler and a second bubbler configured to supply a gas from different positions in a horizontal direction to the processing liquid of the inside of the processing tank; and
a bubbling controller configured to control the first bubbler and the second bubbler,
wherein the image processor comprises a bubbling state determinator configured to determine a state of the gas in the processing liquid based on the bubble data, and
the bubbling controller is further configured to control the first bubbler and the second bubbler based on a determination result of the bubbling state determinator.

12. The substrate liquid-processing apparatus of claim 11, wherein, at the inside of the processing tank, a spot where the first bubbler ejects a gas and a spot where the second bubbler ejects a gas are located opposite to each other with reference to a position where the substrate is disposed.

13. The substrate liquid-processing apparatus of claim 7, wherein the bubbling controller is further configured to perform control by comparing the determination result of the bubbling state determinator with a reference model, and
the reference model is determined based on an amount of the gas supplied into the processing liquid, a concentration of the processing liquid, and a temperature of the processing liquid.

14. The substrate liquid-processing apparatus of claim 7, wherein the bubbling controller is further configured to perform control by comparing the determination result of the bubbling state determinator with a reference table, and
wherein the reference table associates the state of the gas in the processing liquid with an amount of the gas supplied into the processing liquid.

15. The substrate liquid-processing apparatus of claim 1, wherein the bubble data includes data about at least one of a number, density, or size of bubbles.

16. The substrate liquid-processing apparatus of claim 1, wherein the bubble data acquisitor is further configured to acquire the bubble data based on a gray value of the image.

17. The substrate liquid-processing apparatus of claim 1, wherein the imager is further configured to acquire the image of the inside of the processing tank from above.

18. The substrate liquid-processing apparatus of claim 1, wherein the imager is further configured to acquire the image of the inside of the processing tank from a side.

19. The substrate liquid-processing apparatus of claim 2, further comprising:
a bubbler configured to supply a gas to the processing liquid of the inside of the processing tank;
a notifier configured to perform a notification process,
wherein the image processor comprises a bubbling state determinator configured to determine a state of the gas in the processing liquid based on the bubble data, and
the notifier is further configured to perform the notification process based on a determination result of the bubbling state determinator.

20. The substrate liquid-processing apparatus of claim 3, further comprising:
a bubbler configured to supply a gas to the processing liquid of the inside of the processing tank;
a notifier configured to perform a notification process,
wherein the image processor comprises a bubbling state determinator configured to determine a state of the gas in the processing liquid based on the bubble data, and
the notifier is further configured to perform the notification process based on the determination result of the bubbling state determinator.
